(19) United States
(12) Patent Application Publication
(10) Pub. No.: US 2025/0336841 A1
(43) Pub. Date: Oct. 30, 2025

(54) PHOTODETECTION DEVICE

(71) Applicant: SONY SEMICONDUCTOR SOLUTIONS CORPORATION, Kanagawa (JP)

(72) Inventors: Keisuke SATO, Kanagawa (JP); Toshiaki IWAFUCHI, Kanagawa (JP)

(21) Appl. No.: 18/866,757

(22) PCT Filed: May 25, 2023
(86) PCT No.: PCT/JP2023/019558

§ 371 Date: Nov. 18, 2024

(30) Foreign Application Priority Data
May 27, 2022 (JP) 2022-086817

(51) Int. Cl. H01L 23/544; H01L 21/66; H10F 39/00; H10F 39/18

(52) U.S. Cl. CPC H01L 23/544; H01L 22/32; H10F 39/182; H10F 39/811; H01L 2223/5446

(57) ABSTRACT

Flare due to light incident on an outer peripheral side of a pixel region is to be prevented.
A photodetection device includes a semiconductor substrate having a pixel region in which a plurality of pixels that perform photoelectric conversion is disposed. The semiconductor substrate includes: a groove portion that is disposed on the outer peripheral side of the pixel region, has a smaller height than the height of the pixel region, and extends along a plurality of sides; a protruding portion that is provided on the outer peripheral side of the groove portion, has a greater height than the height of the groove portion, and extends along the plurality of sides; and a covering film that covers the entire region of the surface on the light incident surface side of the protruding portion on at least one side of the plurality of sides.

### TECHNICAL FIELD

The present disclosure relates to a semiconductor device.

### BACKGROUND ART

There is a disclosed technique by which a groove portion surrounding the pixel region is provided between a scribe region and the pixel region of each solid-state imaging device singulated from a wafer by dicing, and an uneven structure is provided on a sidewall surface of the groove portion to reduce reflected light from the sidewall surface of the groove portion so that flare due to entry of unnecessary light into the pixel region (see Patent Document 1).

### CITATION LIST

### Patent Document

Patent Document 1: WO 2020/054272 A1

### SUMMARY OF THE INVENTION

### Problems to be Solved by the Invention

In the case of Patent Document 1, the scribe region is formed with silicon similar to that of the pixel region, for example, and has a high reflectance. Therefore, light incident on the upper surface of the scribe region might be reflected to turn into stray light, and be further reflected by a lens module or the like to enter the pixel region. As a result, flare might occur.

In view of the above, the present disclosure is to provide a photodetection device capable of preventing flare due to light incident on the outer peripheral side of the pixel region.

### Solutions to Problems

To solve the above problems, the present disclosure provides a photodetection device that includes a semiconductor substrate having a pixel region in which a plurality of pixels that perform photoelectric conversion is disposed,
in which the semiconductor substrate includes:
a groove portion that is disposed on the outer peripheral side of the pixel region, has a smaller height than the height of the pixel region, and extends along a plurality of sides;
a protruding portion that is provided on the outer peripheral side of the groove portion, has a greater height than the height of the groove portion, and extends along the plurality of sides; and
a covering film that covers the entire region of the surface on the light incident surface side of the protruding portion on at least one side of the plurality of sides.

The reflectance of the covering film may be lower than the reflectance of the semiconductor substrate.

The groove portion may be disposed so as to surround the pixel region, and
the protruding portion may be disposed so as to surround the groove portion.

A diced cutting surface of the semiconductor substrate may be disposed on the outer peripheral side of the protruding portion.

The side covered with the covering film among the plurality of sides of the semiconductor substrate may be a side on which any wire bonding pad is not disposed.

The distance between the pixel region and the groove portion may differ between at least two sides among the plurality of sides of the semiconductor substrate.

The distance on a side on which a wire bonding pad is disposed may be longer than the distance on a side on which any wire bonding pad is not disposed, and
the side covered with the covering film may include a side on which any wire bonding pad is not disposed.

The height of the protruding portion may be the same as the height of the pixel region.

The photodetection device may further include a test terminal disposed on part of the side covered with the covering film, in which
the covering film may cover the surface of the side on which the test terminal is disposed.

A sidewall of the protruding portion at a portion in contact with the groove portion may be a surface extending from the bottom surface of the groove portion to the upper surface of the protruding portion, and the surface may have an uneven structure.

A sidewall of the protruding portion at a portion in contact with the groove portion may be a flat surface extending from the bottom surface of the groove portion to the upper surface of the protruding portion.

The sidewall of the protruding portion at the portion in contact with the groove portion may have a step.

The covering film may include an oxide film having a lower reflectance than the reflectance of the semiconductor substrate.

The covering film may be a stack structure in which a planarizing film containing a resin and the oxide film are stacked.

The planarizing film may be the same material as a film for planarizing the upper surface of a color filter layer disposed on the pixel region.

The thickness of the covering film may be 50 nm or greater, and be 120 nm or smaller.

The present disclosure provides a photodetection device that includes
a semiconductor substrate having a pixel region in which a plurality of pixels that perform photoelectric conversion is disposed,
in which the semiconductor substrate includes:
a groove portion that is disposed on the outer side of the pixel region, has a smaller height than the height of the pixel region, and extends along a plurality of sides; and
a first protruding portion that is disposed on the outer side of the groove portion, has a greater height than the height of the groove portion, and extends along the plurality of sides,
a sidewall of the first protruding portion on a side in contact with the groove portion has an uneven structure, and the upper surface of the first protruding portion is flat.

A predetermined region from the end side of the upper surface continuing to the sidewall of the first protruding portion in contact with the groove portion may be flat.

A sidewall on the outer side of the first protruding portion may include a dicing surface, and,
of the upper surface of the first protruding portion, the predetermined region inwardly away from the dicing surface by at least 5 μm may be flat.

The sidewall of the first protruding portion on the side in contact with the groove portion may be inclined at least a predetermined angle with respect to the normal direction of the upper surface of the first protruding portion.

The first protruding portion may be a single-layer structure containing silicon as a material.

The first protruding portion may be a stack structure,
the first protruding portion may include a covering film disposed so as to be in contact with the upper surface, and a silicon layer stacked on the covering film, and
the reflectance of the covering film may be lower than the reflectance of the silicon layer.

The photodetection device may further include
a scribe region disposed so as to surround the pixel region,
in which the scribe region may include:
a second protruding portion that is disposed on the inner side of the groove portion, has a greater height than the height of the groove portion, and is disposed so as to surround the pixel region;
the groove portion disposed so as to surround the second protruding portion; and
the first protruding portion disposed so as to surround the groove portion.

The photodetection device may further include
wire bonding pads disposed along at least two sides among a plurality of sides of the pixel region,
in which the scribe region may be disposed on the outer side of the pads.

### BRIEF DESCRIPTION OF DRAWINGS

FIG. 1 is a block diagram illustrating a schematic configuration of a photodetection device according to an embodiment.

FIG. 2 is a schematic plan view of part of a first wafer.

FIG. 3 is a schematic plan view of a singulated first chip.

FIG. 4 is a view illustrating a cross-section structure of a camera module.

FIG. 5 is a schematic plan view in which a scribe region on a side of a first chip on which pads are not disposed is enlarged.

FIG. 6 is a cross-sectional view taken along the line A-A defined in FIG. 5.

FIG. 7 is a cross-sectional view in a case where a step is provided on a sidewall surface of a protruding portion.

FIG. 8 is a cross-sectional view in a case where a tapered groove portion is provided.

FIG. 9 is a cross-sectional view in a case where test terminals are provided.

FIG. 10 is a graph showing a relationship between the thickness and the reflectance of a covering film.

FIG. 11A is a view illustrating an example of a cross-section structure of a photodetection device according to a comparative example.

FIG. 11B is a plan view of the photodetection device illustrated in FIG. 11A.

FIG. 12 is a diagram for explaining a cause of occurrence of flare.

FIG. 13A is a cross-sectional view of a photodetection device according to a second embodiment.

FIG. 13B is a plan view of the photodetection device illustrated in FIG. 13A.

FIG. 14 is a plan view illustrating the process of manufacturing the photodetection device according to the second embodiment.

FIG. 15A is a cross-sectional view of a photodetection device according to a modification of the second embodiment.

FIG. 15B is a plan view of the photodetection device illustrated in FIG. 15A.

FIG. 16 is a plan view illustrating the process of manufacturing the photodetection device according to the modification of the second embodiment.

FIG. 17 is a block diagram illustrating an example of a schematic configuration of a vehicle control system.

FIG. 18 is an explanatory diagram illustrating an example of installation positions of an outside-vehicle information detecting section and imaging sections.

### MODE FOR CARRYING OUT THE INVENTION

In the description below, embodiments of a photodetection device will be explained with reference to the drawings. Although principal components of the photodetection devices will be mainly described in the description below, the photodetection devices may include components and functions that are not illustrated in the drawings or described. The following description does not exclude components and functions that are not illustrated in the drawings or described.

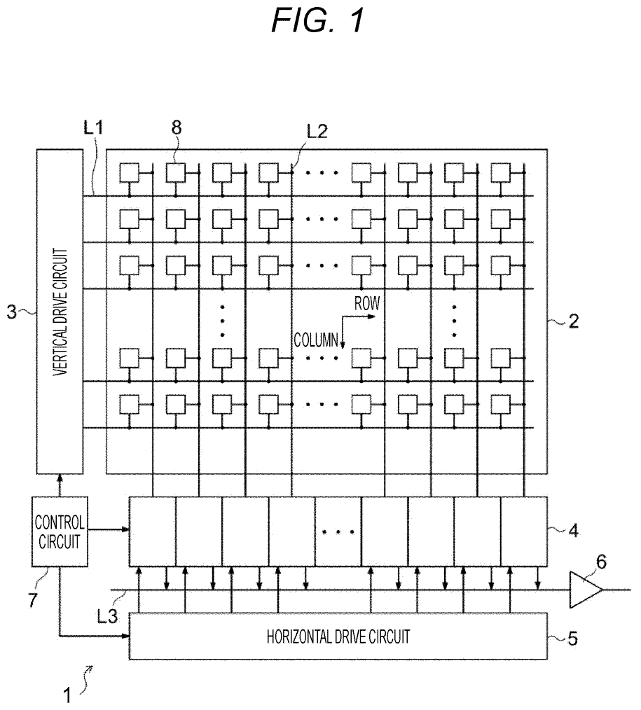

FIG. 1 is a block diagram illustrating a schematic configuration of a photodetection device 1 according to an embodiment. The photodetection device 1 in FIG. 1 is a back-illuminated complementary metal oxide semiconductor (CMOS) image sensor.

The photodetection device 1 in FIG. 1 includes a pixel region 2, a vertical drive circuit 3, column signal processing circuits 4, a horizontal drive circuit 5, an output circuit 6, and a control circuit 7. The photodetection device 1 in FIG. 1 is also called a solid-state imaging device.

The pixel region 2 includes a plurality of pixels 8 arranged in two-dimensional directions (a row direction and a column direction) on a semiconductor substrate. The semiconductor substrate is a silicon substrate, for example. A pixel 8 includes a photoelectric conversion element and a pixel circuit (not illustrated in FIG. 1). The pixel circuit includes a transfer transistor, a reset transistor, a selection transistor, an amplification transistor, and the like, and generates a pixel signal that is a voltage signal corresponding to the amount of electric charge photoelectrically converted by the photoelectric conversion element.

The vertical drive circuit 3 includes a shift register, for example, and sequentially drives a plurality of row selection lines L1 arranged in the column direction. In this manner, the vertical drive circuit 3 selects each pixel 8 in the pixel region 2 row by row.

The column signal processing circuits 4 are provided for the respective pixel columns arranged in the column direction. Specifically, a vertical signal line L2 is provided for each pixel column, and the column signal processing circuits 4 are provided for the respective corresponding vertical signal lines L2. The column signal processing circuits 4 perform signal processing such as a correlated double sampling (CDS) process for detecting a potential difference between a reset level and a pixel signal level of each pixel 8 and removing fixed pattern noise unique to the pixel, and an analog-digital conversion process. The column signal processing circuits 4 output digital pixel signals.

The horizontal drive circuit 5 includes a shift register, for example. The horizontal drive circuit 5 sequentially transfers the digital pixel signals output from the column signal processing circuits 4 to a horizontal signal line. The output circuit 6 is connected to the horizontal signal line. The output circuit 6 performs various kinds of signal processing on the digital pixel signals on the horizontal signal line, and then outputs the signals. The signal processing to be performed by the output circuit 6 is buffering, black level adjustment, column variation correction, and the like, for example.

The control circuit 7 generates a clock signal and a control signal serving as references for operations of the vertical drive circuit 3, the column signal processing circuits 4, the horizontal drive circuit 5, and the like, on the basis of a vertical synchronization signal, a horizontal synchronization signal, and a master clock signal. The control circuit 7 outputs the generated clock signal and control signal to the vertical drive circuit 3, the column signal processing circuits 4, the horizontal drive circuit 5, and the like.

The entire photodetection device 1 in FIG. 1 may be formed on one semiconductor substrate, or may be formed on two or more semiconductor substrates that are to be stacked. When a plurality of semiconductor substrates is stacked, electrical conduction and bonding between the substrates are performed with Cu-Cu bonding, bumps, vias, or the like.

An example of the photodetection device 1 having a stack structure is formed by stacking a first semiconductor substrate on which the pixel region 2 is disposed, and a second semiconductor substrate on which the vertical drive circuit 3, the column signal processing circuits 4, the horizontal drive circuit 5, the output circuit 6, and the control circuit 7 are disposed. Note that at least one of the vertical drive circuit 3, the column signal processing circuits 4, the horizontal drive circuit 5, the output circuit 6, and the control circuit 7 may be disposed on the first semiconductor substrate. Hereinafter, the first semiconductor substrate will be sometimes referred to as a first chip, and the second semiconductor substrate will be sometimes referred to as a second chip.

The first chip is one chip that is cut out from a first wafer. A plurality of first chips is formed on the first wafer, and is singulated into individual first chips with a dicing blade. Likewise, the second chip is one chip that is cut out from a second wafer. A plurality of second chips is formed on the second wafer, and is singulated into individual second chips with a dicing blade.

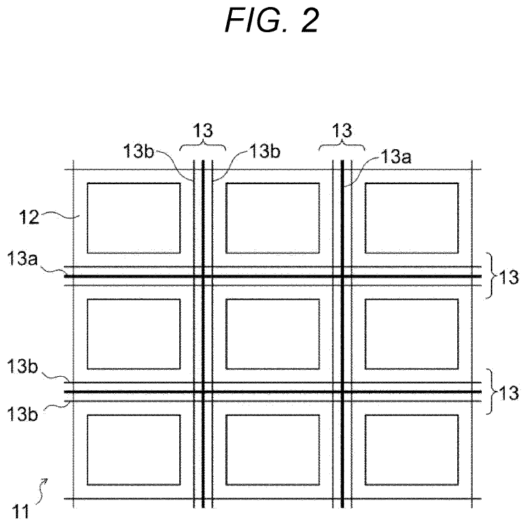

FIG. 2 is a schematic plan view of part of a first wafer 11. On the first wafer 11, a plurality of first chips 12 is disposed at regular intervals in a two-dimensional direction, and scribe regions 13 are provided in a lattice-like pattern between two adjacent first chips 12. The scribe regions 13 are regions where the wafers are cut out with a dicing blade (not illustrated). More specifically, the first wafer 11 is cut along thick line regions 13a in the scribe regions 13.

In the scribe regions 13, groove portions 13b extending in the longitudinal direction of the scribe regions 13 are arranged in a lattice-like pattern. The groove portions 13b are disposed closer to the pixel regions 2 than the thick line regions 13a indicating the cutting surfaces. When the wafer is cut with a dicing blade along the thick line regions 13a in the scribe regions 13, there is a possibility that cracks will appear in the vicinities of the cutting surfaces of the wafer, or part of a layer will peel off. To prevent such cracks and peeling from reaching the pixel regions 2, the scribe regions 13 have the groove portions 13b formed between the pixel regions 2 and the cutting surfaces. As the groove portions 13b are provided in the scribe regions 13, cracks and peeling of the cutting surfaces do not reach the pixel regions 2.

FIG. 2 illustrates a plan view of the first wafer 11. Likewise, in the second wafer, scribe regions 13 having groove portions 13b are arranged in a lattice-like pattern between two adjacent second chips.

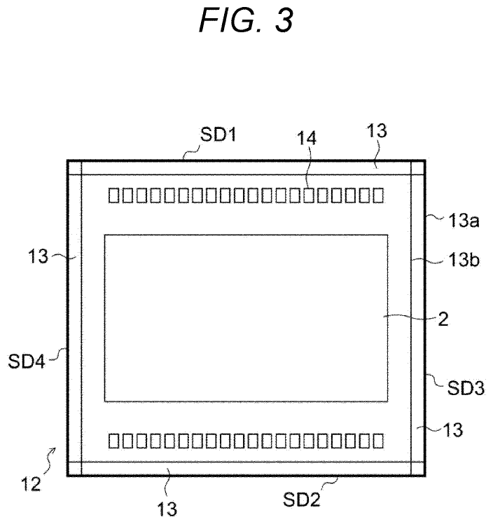

FIG. 3 is a schematic plan view of one cut first chip 12. The first chip 12 illustrated in FIG. 3 has a rectangular shape, the pixel region 2 is disposed in the central portion, and a plurality of pads 14 for wire bonding is disposed along two sides facing each other (hereinafter referred to as the first side SD1 and the second side SD2). Meanwhile, pads 14 are not disposed along two sides facing each other in directions different from the above by 90 degrees (hereinafter referred to as the third side SD3 and the fourth side SD4).

Although a scribe region 13 described above is provided on the first to fourth sides SD1 to SD4 of the first chip 12, the distance between the scribe region 13 and the pixel region 2 differs between the first and second sides SD1 and SD2, and the third and fourth sides SD3 and SD4. More specifically, the distance between the scribe region 13 and the pixel region 2 on the first side SD1 and the second side SD2 is longer than the distance between the scribe region 13 and the pixel region 2 on the third side SD3 and the fourth side SD4.

The reason for increasing the distance between the scribe region 13 and the pixel region 2 on the first side SD1 and the second side SD2 is to prevent light incident on and reflected by bonding wires from entering the pixel region 2.

As described above, since the distance between the pixel region 2 and the scribe region 13 differs between the first and second sides SD1 and SD2 on which the pads 14 for wire bonding are disposed, and the third and fourth sides SD3 and SD4 on which the pads 14 are not disposed, the situations of generation of flare to be caused by light reflected by the scribe region 13 vary.

Specifically, in a case where the distance between the pixel region 2 and the scribe region 13 is short, there is a high possibility that light incident on and reflected by the scribe region 13 will hit some obstacle in a camera module, and be reflected by and incident on the pixel region 2. On the other hand, in a case where the distance between the pixel region 2 and the scribe region 13 is long, even if light reflected by the scribe region 13 is reflected by some obstacle, the possibility of the light entering the pixel region 2 becomes lower.

Therefore, in the present embodiment, measures against flare are taken for the sides SD3 and SD4 on which the pads 14 for wire bonding are not disposed among the plurality of sides forming the scribe region 13. Note that, in the scribe region 13, the sides SD1 and SD2 on which the pads 14 for wire bonding are disposed may also be subjected to a flare countermeasure in a manner similar to that for the sides on which the pads 14 are not disposed.

As described later, the flare countermeasure adopted by the present embodiment is to cover at least the entire upper surfaces of the sides SD3 and SD4 of the scribe region 13 where the pads 14 are not disposed, with a covering film. As a so-called antireflection film is adopted as the covering film, reflection of light incident on the scribe region 13 can be reduced, and light does not enter the pixel region 2.

In FIG. 3, the pads 14 are disposed on two sides (the first side SD1 and the second side SD2) among the four sides of the rectangular first chip 12, but the sides on which the pads 14 are disposed are not necessarily two sides facing each other. In some cases, the pads 14 may be disposed on only one side, or the pads 14 may be disposed on three sides. As described above, in the present embodiment, at least the entire regions of the sides on which the pads 14 are not disposed in the scribe region 13 are covered with the covering film.

The second chip stacked on the first chip 12 is disposed on the opposite side in the light incident direction, and does not have the pixel region 2. Because of this, there is no need to cover the scribe region 13 of the second chip.

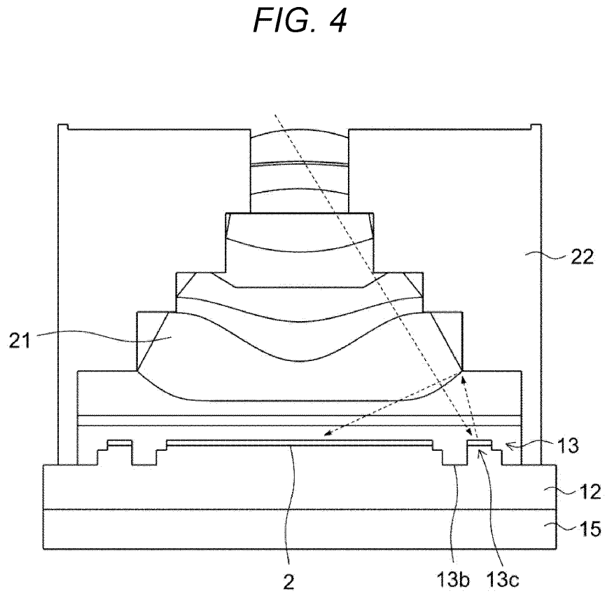

The first chip 12 and the second chip that are stacked are incorporated into a camera module 20, for example. FIG. 4 is a diagram illustrating a cross-section structure of the camera module 20. The camera module 20 in FIG. 4 has a structure in which a plurality of imaging lenses 21 is disposed above the stacked first chip 12 and second chip 15. The plurality of imaging lenses 21 is supported by a lens holder 22. Although not illustrated in FIG. 4, a lens barrel that moves at least some of the imaging lenses 21 in the optical axis direction for focusing may be provided. When light is made to enter an obstacle such as an adhesive member for securing the imaging lenses 21 to the lens holder 22 or the lens barrel, the light is reflected. The direction of reflection at that time depends on the light incident direction and the surface shape of the obstacle, and in some cases, the light enters the pixel region 2. It is difficult to grasp the traveling direction of the light reflected by the obstacle in advance, and control the reflection direction. To reduce entry of light into the pixel region 2, it is effective to reduce reflection of light in the scribe region 13.

### First Embodiment

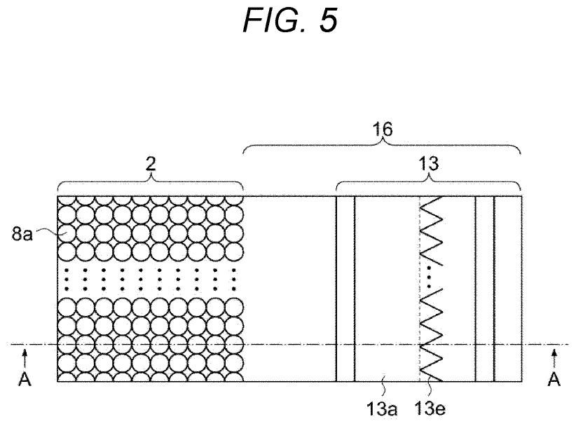

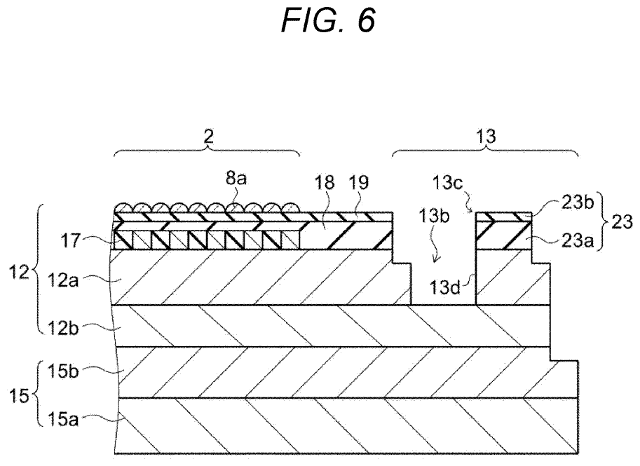

In FIG. 4, there is a possibility that light incident on the scribe region 13 in the peripheral region of the first chip 12 will be reflected, be further reflected by an obstacle such as the lens holder 22 in the camera module 20 as indicated by a dashed line, and enter the pixel region 2. Light that has entered the pixel region 2 causes flare. A photodetection device 1 according to the first embodiment characteristically takes measures against flare so as to reduce light reflected from the scribe region 13, even though light enters the scribe region 13. FIG. 5 is an enlarged schematic plan view of a scribe region 13 of a side of the first chip 12 on which pads 14 are not disposed. Meanwhile, FIG. 6 is a cross-sectional view taken along the line A-A in FIG. 5. FIG. 6 illustrates a cross-section structure in a stack structure in which the first chip 12 and the second chip 15 are stacked.

In the present specification, an outer peripheral side of the pixel region 2 is referred to as a peripheral region 16, as illustrated in FIG. 5. A scribe region 13 is provided in the peripheral region 16 as described above. As illustrated in FIG. 3, the scribe region 13 is annularly disposed along each side of the first chip 12, and has a constant width. Further, the scribe region 13 has a groove portion 13b and a protruding portion 13c as illustrated in FIG. 6. In the pixel region 2, a color filter layer 17 is disposed on a first semiconductor substrate 12a, and on-chip lenses 8a are disposed thereon. In this manner, the groove portion 13b is disposed so as to surround the pixel region 2, and the protruding portion 13c is disposed so as to surround the groove portion 13b. A diced cutting surface of the first chip 12 is located on the outer peripheral side of the protruding portion 13c.

As illustrated in FIG. 6, the first chip 12 is a stack structure in which the first semiconductor substrate 12a and a first wiring layer 12b are stacked. Further, the second chip 15 is a stack structure in which a second semiconductor substrate 15a and a second wiring layer 15b are stacked. The groove portion 13b is formed by partially scraping off the semiconductor substrate formed with silicon, for example. In the example in FIG. 6, the bottom surface of the groove portion 13b has reached the first wiring layer 12b, and the first semiconductor substrate 12a has been entirely removed in the groove portion 13b. As a modification, the groove portion 13b may be formed so that part of the first semiconductor substrate 12a remains.

The height of the groove portion 13b is smaller than the height of the pixel region 2. The protruding portion 13cincludes the first semiconductor substrate 12a, and the height of the protruding portion 13c is greater than the height of the groove portion 13b. The height of the protruding portion 13c is the same as the height of the pixel region 2. Note that, as illustrated in FIG. 6, at least part of the first semiconductor substrate 12a on the outer peripheral side of the protruding portion 13c has been removed, and the height thereof is smaller than that of the protruding portion 13c.

As illustrated in FIG. 5, an uneven structure 13e is provided on a sidewall surface 13d of the protruding portion 13c at a portion where the protruding portion 13c is in contact with the groove portion 13b. FIG. 5 illustrates an example in which the uneven structure 13e having a triangular planar shape is provided, but the shape and the size of the uneven structure 13e are not limited to any specific ones. As the uneven structure 13e is provided, light incident on the sidewall surface 13d can be scattered, and it is possible to avoid the possibility that light based on reflected light from the sidewall surface 13d will enter the pixel region 2.

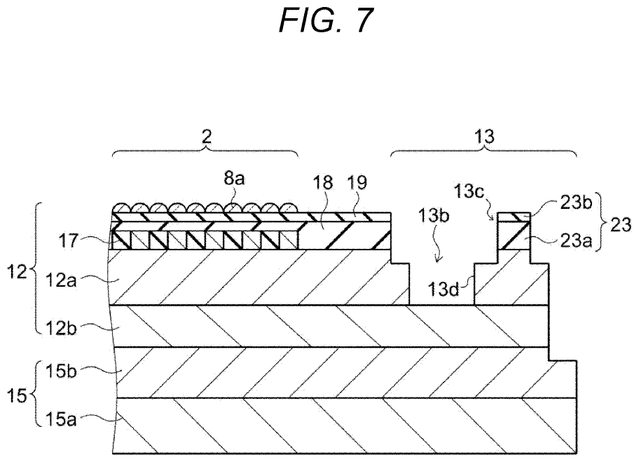

The sidewall surface 13d of the protruding portion 13c does not necessarily have the uneven structure 13e, and may be a flat surface. Further, as illustrated in FIG. 7, a step may be provided on the sidewall surface 13d of the protruding portion 13c. In a case where a step is provided, the uneven structure 13e may be provided on each step-like surface. As a step is provided on the sidewall surface 13d of the protruding portion 13c, the area of the upper surface of the protruding portion 13c can be made smaller. As the area of the upper surface of the protruding portion 13c becomes smaller, light is less likely to be incident on the upper surface of the protruding portion 13c, and reflected light from the upper surface of the protruding portion 13c can be reduced.

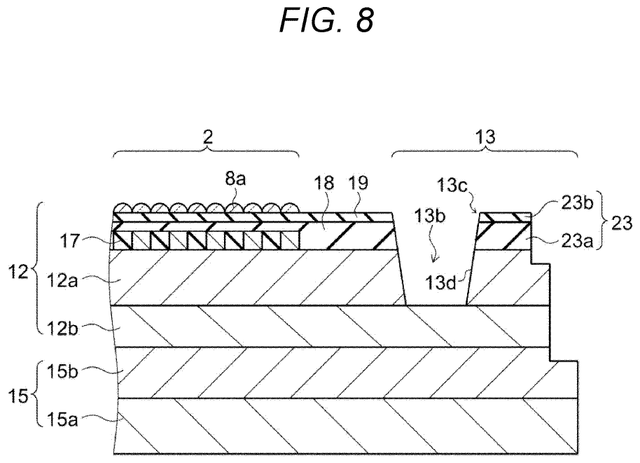

Further, as illustrated in FIG. 8, the sidewall surface 13d of the protruding portion 13c may have a tapered shape extending in an oblique direction with respect to the normal direction of the light incident surface. As the sidewall surface 13d extends in an oblique direction, the area of the upper surface of the protruding portion 13c can be made smaller. Note that, in the case in FIG. 8, the upper surface of the protruding portion 13c is also covered with a covering film 23. Further, the sidewall surface 13d may have the uneven structure 13e as in FIG. 6.

As illustrated in FIGS. 6 to 8, the upper surface of the protruding portion 13c is covered with the covering film 23. The reflectance of the covering film 23 is lower than the reflectance of the semiconductor substrate forming the protruding portion 13c. As the reflectance of the covering film 23 is made lower than the reflectance of the semiconductor substrate, reflection of light incident on the covering film 23 can be reduced, reflected light generated by the light reflected by the covering film 23 does not enter the pixel region 2, and thus, flare can be prevented.

The covering film 23 may have a stack structure, for example. The covering film 23 in FIGS. 6 to 8 shows an example of a two-layer structure. The covering film 23 in FIG. 6 has a stack structure in which an oxide film 23b is stacked on a planarizing film 23a. The planarizing film 23a is a film formed with an acrylic thermosetting resin, for example. The planarizing film 23a is the same material as a planarizing film 18 for planarizing the upper surface of the color filter layer 17 on the first semiconductor substrate 12a of the pixel region 2, and the planarizing film 23a is disposed on the upper surface of the scribe region 13 in the step of disposing the planarizing film 18 on the color filter layer 17.

The oxide film 23b is an oxide film formed in a low-temperature process, for example, and is also called a low temperature oxide (LTO). In the step of forming a LTO 19 on the planarizing film 18 of the pixel region 2, the oxide film 23b formed with a LTO is formed on the planarizing film 23a in the scribe region 13.

As described above, the covering film 23 provided in the scribe region 13 is formed in the step of stacking the planarizing film 18 and the LTO 19 on the color filter layer 17 on the first semiconductor substrate 12a in the pixel region 2. Accordingly, any additional process is unnecessary, and there is no possibility of an increase in manufacturing cost.

The reflectance of the oxide film 23b forming the covering film 23 that covers the protruding portion 13c in the scribe region 13 is about ¼ to ⅕ of the reflectance of the semiconductor substrate formed with silicon. For example, when the reflectance of the semiconductor substrate formed with silicon is about 40 to 50%, the reflectance of the covering film 23 including the oxide film 23b is about 0 to 10%.

As described above, the upper surface of the protruding portion 13c in the scribe region 13 is covered with the covering film 23 having a low reflectance. Thus, the occurrence of flare to be caused by light reflected by the protruding portion 13c can be prevented.

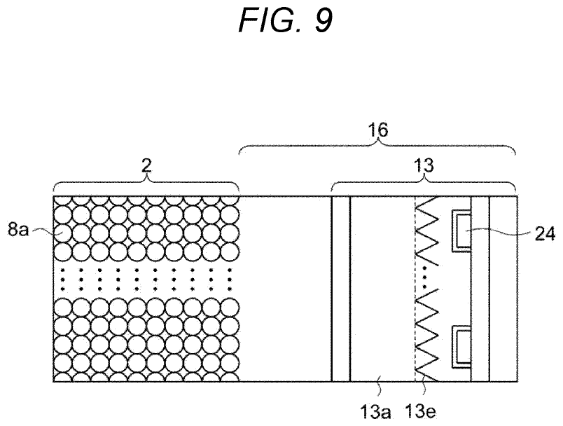

As illustrated in FIG. 9, there are cases where one or a plurality of test terminals 24 is provided on the sides of the scribe regions 13 in which the pads 14 are not disposed. The test terminal(s) 24 is (are) provided to inspect the waveform of the corresponding signal node(s) in the photodetection device 1 by bringing a probe (not illustrated) into contact during an inspection step.

Since the probe is repeatedly attached to and detached from the test terminals 24, the covering film 23 is formed to protect the peripheries of the test terminals 24. In the present embodiment, the entire regions of the sides on which the pads 14 are not disposed are covered with the covering film 23. Accordingly, the peripheries of the test terminals 24 are also covered with the covering film 23, and a separate step for covering the peripheries of the test terminals 24 with the covering film 23 is not necessary.

As illustrated in FIGS. 6 to 8, there is a plurality of candidates for the cross-section structure of the scribe region 13, and any of the candidates may be adopted. The width of the protruding portion 13c is desirably 10 μm or greater. Alternatively, the width of the protruding portion 13c is desirably equal to or greater than ½ of the distance from the end portion of the first chip on the side of the groove portion 13b to the cutting surface of the first chip 12. Further, in a case where the uneven structure 13e is provided, the covering film 23 may also be formed on the uneven structure 13e, but may not be provided.

Furthermore, when the thickness of the covering film 23 is too small, there is a possibility that light will not be absorbed or scattered, and will be reflected. According to simulations conducted by the present inventor, the thickness of the covering film 23 is desirably 10 nm or greater. In particular, when the thickness of the covering film 23 is 50 nm or greater, the reflectance inherent to the material forming the covering film 23 can be obtained, and the reflectance can be made smaller than that of the semiconductor substrate.

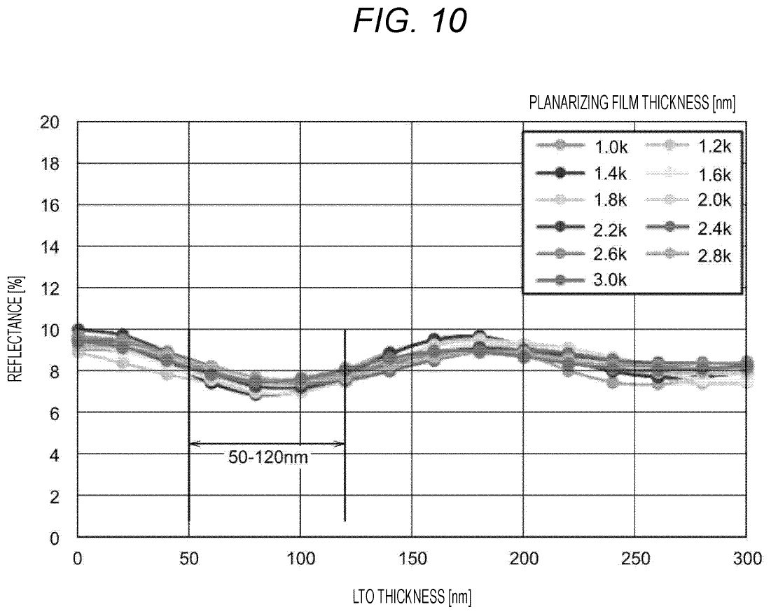

FIG. 10 is a graph showing the relationship between the thickness and the reflectance of the covering film 23, and illustrates the results of simulations of the reflectance of the covering film 23 in a case where the thicknesses of the LTO 23b and the planarizing film 23a constituting the covering film 23 were variously changed. In FIG. 10, the abscissa axis indicates the film thickness of the LTO 23b, and the ordinate axis indicates the reflectance. FIG. 10 shows the reflectance of the covering film 23 when the thickness of the LTO 23b was changed to from 0 to 300 nm [nm] for each of eleven thicknesses from 1.0 k to 3.0 k of the planarizing film 23a, with the reference thickness of the planarizing film 23a being k [nm]. The reflectance tends to periodically change as the thickness of the LTO 23b changes. However, the reflectance is the lowest when the thickness of the LTO 23b is in the range of 50 to 120 [nm]. As can be seen from this result, the thickness of the LTO 23b is desirably 50 to 120 [nm].

As described above, in the first embodiment, the upper surface of the protruding portion 13c on the outer peripheral side of the groove portion 13b in the scribe region 13 is covered with the covering film 23, and the reflectance of the covering film 23 is set to about ¼ to ⅕ of the reflectance of the semiconductor substrate. Accordingly, light that has entered the protruding portion 13c is hardly reflected, the light that has entered the protruding portion 13c can be prevented from being reflected by an obstacle and entering the pixel region 2, and thus, the occurrence of flare can be prevented.

### Second Embodiment

As illustrated in FIG. 7, in a case where a step is provided on the sidewall surface 13d of the protruding portion 13c, there is a possibility that light incident on the step will be reflected and enter the pixel region 2 as flare.

Also, in the first embodiment, the structure of the protruding portion 13c provided along the sides on which the pads 14 are not disposed has been mainly described. However, measures against flare are also necessary for the protruding portion provided along the sides on which the pads 14 are disposed.

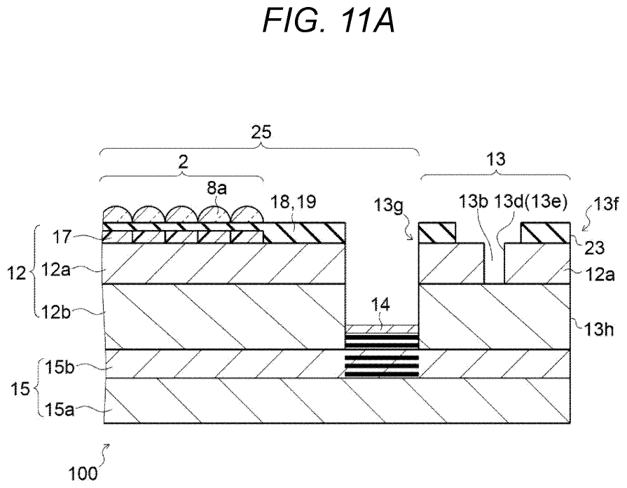

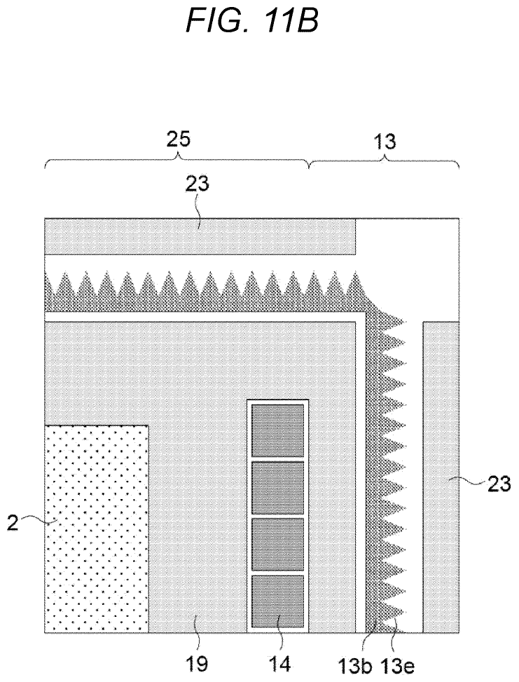

FIG. 11A is a view illustrating an example of a cross-section structure of a photodetection device 100 according to a comparative example that causes flare. FIG. 11B is a plan view of the photodetection device 100 illustrated in FIG. 11A.

As illustrated in FIG. 11B, the pads 14 for wire bonding are disposed along at least two sides of a plurality of sides of the pixel region 2. In the present specification, a range including the pixel region 2 and the pads 14 is referred to as a chip region 25, and the outside of the chip region 25 is referred to as the scribe region 13. The scribe region 13 is disposed so as to surround the chip region 25.

The scribe region 13 in the comparative example includes a first protruding portion 13f, a groove portion 13b, and a second protruding portion 13g, each of which is annularly disposed. The first protruding portion 13f is disposed so as to surround the chip region 25, the second protruding portion 13g, and the groove portion 13b. The groove portion 13b is disposed so as to surround the chip region 25 and the second protruding portion 13g. The second protruding portion 13g is disposed so as to surround the chip region 25.

The sidewalls 13d of the first protruding portion 13f on the sides in contact with the groove portion 13b have an uneven structure 13e as illustrated in FIG. 11B. Since light incident on the uneven structure 13e is dispersed and reflected, flare is prevented from entering the pixel region 2.

The first protruding portion 13f and the second protruding portion 13g in the photodetection device 100 according to the comparative example each have a stack structure in which the covering film 23 is disposed on the first semiconductor substrate 12a. The first semiconductor substrate 12a is a silicon substrate, for example, and the covering film 23 is an organic film, for example. The covering film 23 is disposed on part of the upper surfaces of the first protruding portion 13fand the second protruding portion 13g, and a step is provided at the portion where the covering film 23 is disposed and the portion where the first semiconductor substrate 12a is exposed. There is a possibility that light incident on the step portion will turn into flare and enter the pixel region 2.

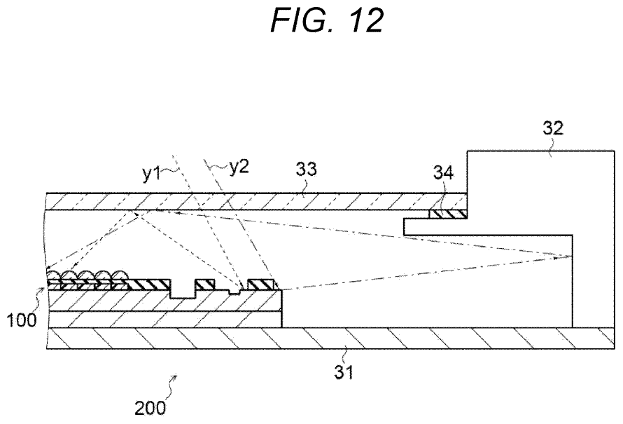

FIG. 12 is a view for explaining a cause of occurrence of flare. FIG. 12 illustrates a cross-section structure of a principal portion of a camera module 200 including the photodetection device 100 according to the comparative example. A frame 32 is attached to a support substrate 31 of the photodetection device 100. An IR cut filter 33 is disposed so as to face the pixel region 2 of the photodetection device 100. The IR cut filter 33 is joined to the frame 32 with an adhesive 34.

At least part of light incident on the step portion of the first protruding portion 13f is reflected by the step portion as indicated by a light beam y1, is then further reflected by the IR cut filter 33, and enters the pixel region 2.

Further, in a case where there is a step on the outer peripheral side of the upper surface of the first protruding portion 13f, the light is reflected by the step portion, is reflected by the frame 32, is then further reflected by the IR cut filter 33, and enters the pixel region 2, as indicated by a light beam y2.

As described above, in a case where there is a step near the upper surface of the first protruding portion 13f, flare is likely to enter the pixel region 2. A photodetection device 1a according to a second embodiment is characterized in that any step is not provided in the vicinity of the upper surface of the first protruding portion 13f.

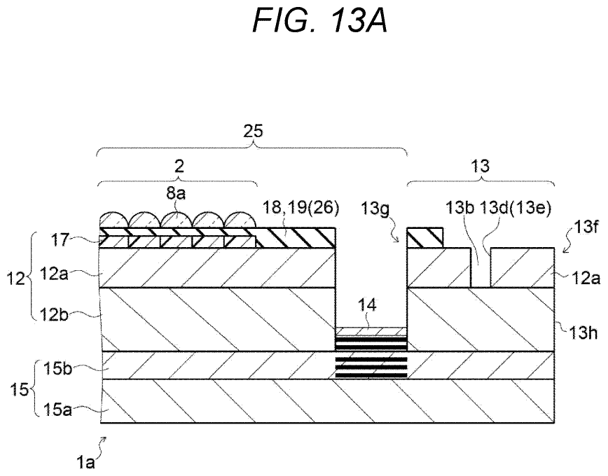

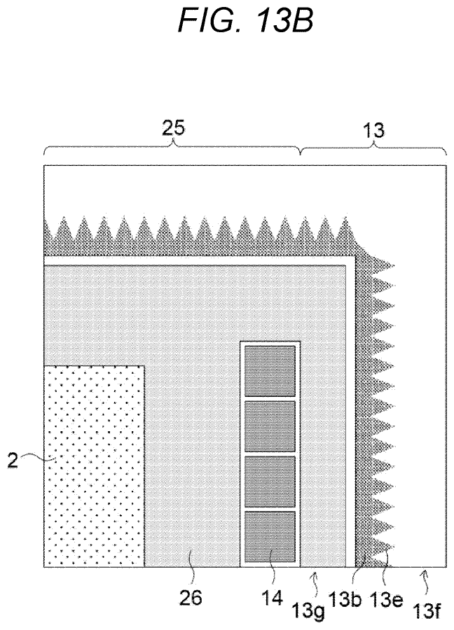

FIG. 13A is a cross-sectional view of the photodetection device 1a according to the second embodiment, and FIG. 13B is a plan view of the photodetection device 1a illustrated in FIG. 13A. The photodetection device 1a according to the second embodiment differs from the photodetection device 100 according to the comparative example in the configuration of the scribe region 13.

The scribe region 13 according to the second embodiment includes a second protruding portion 13g disposed so as to surround the chip region 25, a groove portion 13b disposed so as to surround the second protruding portion 13g, and a first protruding portion 13f arranged so as to surround the groove portion 13b.

The first protruding portion 13f and the second protruding portion 13g have a greater height than that of the groove portion 13b. FIG. 13B illustrates an example in which the first protruding portion 13f and the second protruding portion 13g are disposed in an annular shape. However, the first protruding portion 13f and the second protruding portion 13g are not necessarily annular, and are only required to extend along a plurality of sides.

The sidewalls 13d of the first protruding portion 13f on the sides in contact with the groove portion 13b have an uneven structure 13e as illustrated in FIG. 13B. The upper surface of the first protruding portion 13f is flat. As the upper surface of the first protruding portion 13f is flat, it is possible to lower the possibility that light that has entered and been reflected by the upper surface will enter the pixel region 2.

The entire upper surface of the first protruding portion 13f is not necessarily flat. For example, it is desirable to planarize a predetermined region from the edges of the upper surface continuing to the sidewalls 13d of the first protruding portion 13f on the sides in contact with the groove portion 13b. The outer sidewall surfaces of the first protruding portion 13f are dicing surfaces 13h. Of the upper surface of the first protruding portion 13f, the predetermined region is a region that is at least 5 μm away inward from the dicing surfaces 13h, for example. Of the upper surface of the first protruding portion 13f, the region within 5 μm from the dicing surfaces 13h might have a rough surface at the time of dicing. Therefore, the upper surface excluding this region is the above-described predetermined region.

The sidewalls 13d of the first protruding portion 13f on the sides in contact with the groove portion 13b may be inclined at a predetermined angle or more with respect to the normal direction of the upper surface of the first protruding portion 13f. The predetermined angle is an angle at which light incident on the sidewall 13d of the first protruding portion 13f is not reflected by the sidewall 13d, and eventually enters the pixel region 2. There are a case where the light reflected by the sidewall 13d directly enters the pixel region 2, and a case where the light is again reflected by the IR cut filter 33 or the like and then enters the pixel region 2, and the predetermined angle may vary depending on the placement locations of the respective members of the camera module 20. In general, the greater the predetermined angle with respect to the normal direction, the less likely light incident on the sidewall 13d is to enter the pixel region 2.

The first protruding portion 13f in FIG. 13A has a single-layer structure, and is formed with silicon, for example. Since the upper surface of the first protruding portion 13f is flat and has no steps, light propagating in the paths indicated by the lines y1 and y2 with arrows in FIG. 12 is not generated, and flare can be prevented.

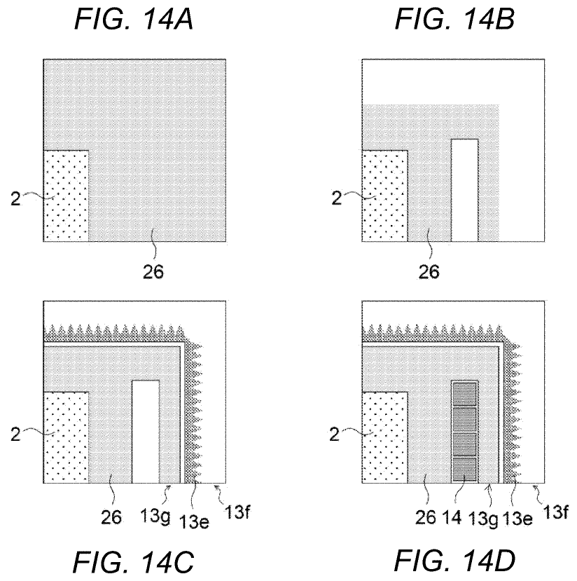

FIG. 14 is plan views illustrating the process of manufacturing the photodetection device 1a according to the second embodiment. First, as illustrated in FIG. 14A, the periphery of the pixel region 2 is covered with an organic film 26. The organic film 26 is an acrylic resin film containing polymethyl methacrylate, for example. Through the process in FIG. 14A, the region other than the pixel region 2 in the chip region 25 and the entire region of the scribe region 13 are covered with the organic film 26. Note that the organic film 26 may have a two-layer structure including the planarizing film 18 and the LTO 19 as described in the first embodiment.

Next, as illustrated in FIG. 14B, the organic film 26 in the region of the pads 14 in the chip region 25 is removed, and the organic film 26 in the scribe region 13 is removed. The organic film 26 is removed by an etching process, for example.

Next, as illustrated in FIG. 14C, the first semiconductor substrate 12a in the scribe region 13 is partially scraped off, to form the groove portion 13b in the scribe region 13. As the groove portion 13b is formed, the annular second protruding portion 13g is formed on the inner side of the groove portion 13b, and the annular first protruding portion 13f is formed on the outer side of the groove portion 13b. Further, the uneven structure 13e is formed on the sidewalls 13d of the groove portion 13b in contact with the first protruding portion 13f. More specifically, the uneven structure 13e is a plurality of pyramidal members disposed along the sidewall surfaces 13d of the first protruding portion 13f. The pyramidal members are polygonal pyramids such as triangular pyramids or quadrangular pyramids.

The uneven structure 13e can be formed by a direct self-assembly (DSA) technology, for example. Specifically, a diblock copolymer is applied to the sidewall surfaces 13d of the first protruding portion 13f in contact with the groove portion 13b. As the diblock copolymer, polystyrene-polymethyl methacrylate (PS-PMMA) can be adopted, for example. Further, the scribe region 13 excluding the groove portion 13b, and the chip region 25 are covered with a resist.

Next, the applied diblock copolymer is irradiated with ultraviolet rays. As a result, phase separation structures of several to several tens of nm are formed by repulsion between the polystyrene and the polymethyl methacrylate. Thus, the polymethyl methacrylate forms a sphere, and the polystyrene is crosslinked to form an etching plate, for example.

The shape and the pitch of the phase separation structure are adjusted by controlling the volume ratio between the polystyrene and the polymethyl methacrylate. Next, the sphere of the polymethyl methacrylate is removed, and isotropic dry etching is performed with the polystyrene etching plate, so that a plurality of pyramidal members are formed on the sidewall surfaces 13d of the first protruding portion 13f.

Instead of forming a plurality of pyramidal members on the sidewall surfaces 13d of the first protruding portion 13f, a moth's eye structure in which a large number of minute pyramidal members are disposed on the sidewall surfaces may be formed.

Next, as illustrated in FIG. 14D, openings for the pads 14 are formed in the chip region 25. After that, dicing is performed on the dicing surfaces 13h, which are end surface of the first protruding portion 13f, to perform singulation. Test pads (not illustrated) may be disposed on the outer side of the wire bonding pads 14 of the photodetection device 1a in some cases. Since the pads 14 are formed with a metal material such as aluminum, some of the pads 14 remain curled up when dicing is performed at the positions where the pads 14 overlap the test pads. The curled-up pads 14 reflect light, and therefore, there is a possibility that light incident on the curled-up pads 14 and are reflected will enter the pixel region 2 as flare. Because of this, it is desirable to dispose the test pads on the outer side of the dicing position.

### Modification of the Second Embodiment

The first protruding portion 13f and the second protruding portion 13g may have a stack structure, and the covering film 23 may be disposed so as to be in contact with the upper surfaces of the first protruding portion 13f and the second protruding portion 13g to planarize the upper surface of the covering film 23.

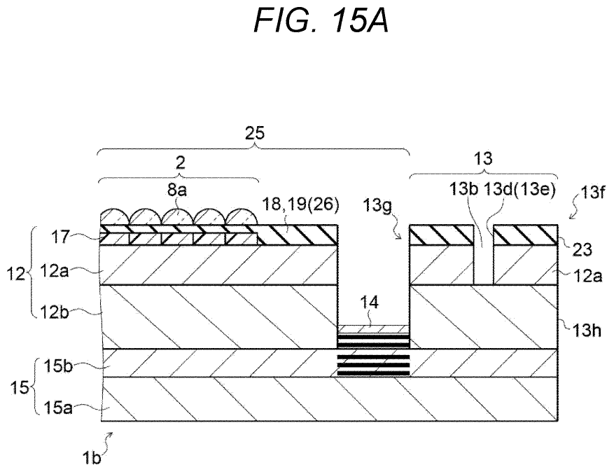

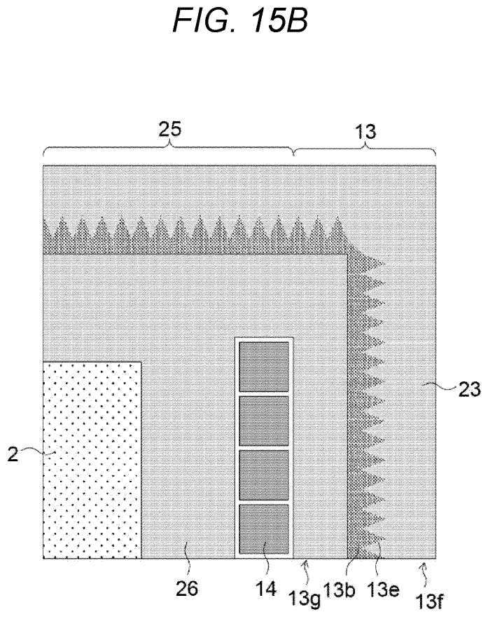

FIG. 15A is a cross-sectional view of a photodetection device 1b according to a modification of the second embodiment, and FIG. 15B is a plan view of the photodetection device 1b illustrated in FIG. 15A. The photodetection device 1b in FIGS. 15A and 15B differs from the photodetection device 1 illustrated in FIGS. 13A and 13B in that the first protruding portion 13f and the second protruding portion 13g are stack structures.

The first protruding portion 13f and the second protruding portion 13g are stack structures in which the covering film 23 is stacked on the first semiconductor substrate 12a. The reflectance of the covering film 23 is lower than the reflectance of the first semiconductor substrate 12a. The covering film 23 is the same material as the organic film 26, for example.

Since the first protruding portion 13f in FIGS. 15A and 15B does not have a step near the upper surface, reflection of light that would eventually enter the pixel region 2 hardly occurs. In addition to this, the upper surface of the first protruding portion 13f is covered with the covering film 23, and thus, reflection of light hardly occurs.

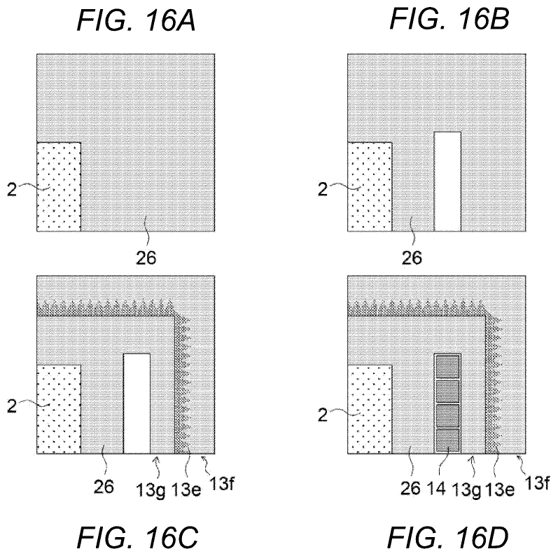

FIG. 16 is plan views illustrating the process of manufacturing the photodetection device 1b according to the modification of the second embodiment. First, as illustrated in FIG. 16A, the periphery of the pixel region 2 is covered with an organic film 26.

Next, as illustrated in FIG. 16B, the organic film 26 in the region of the pads 14 in the chip region 25 is removed. Although the organic film 26 in the scribe region 13 is removed in FIG. 14B, the organic film 26 in the scribe region 13 remains as it is in FIG. 16B. The organic film 26 in the scribe region 13 functions as the covering film 23.

Next, as illustrated in FIG. 16C, the groove portion 13b is formed in the scribe region 13. Uneven structures 13e are formed on the sidewall surfaces 13d of the first protruding portion 13f in contact with the groove portion 13b in the similar process as in FIG. 14C.

Next, as illustrated in FIG. 16D, openings for the pads 14 are formed in the chip region 25.

As described above, in the second embodiment, the upper surface of the first protruding portion 13f in contact with the groove portion 13b formed in the scribe region 13 is planarized.

Accordingly, even if light incident on the upper surface of the first protruding portion 13f is reflected, the light does not enter the pixel region 2 eventually. Thus, flare can be prevented.

### Example Applications

The technology according to the present disclosure can be applied to various products. For example, the technology according to the present disclosure may also be embodied as a device mounted on any kind of mobile object such as an automobile, an electric automobile, a hybrid electric automobile, a motorcycle, a bicycle, a personal mobility, an airplane, a drone, a ship, a robot, a construction machine, an agricultural machine (a tractor), or the like.

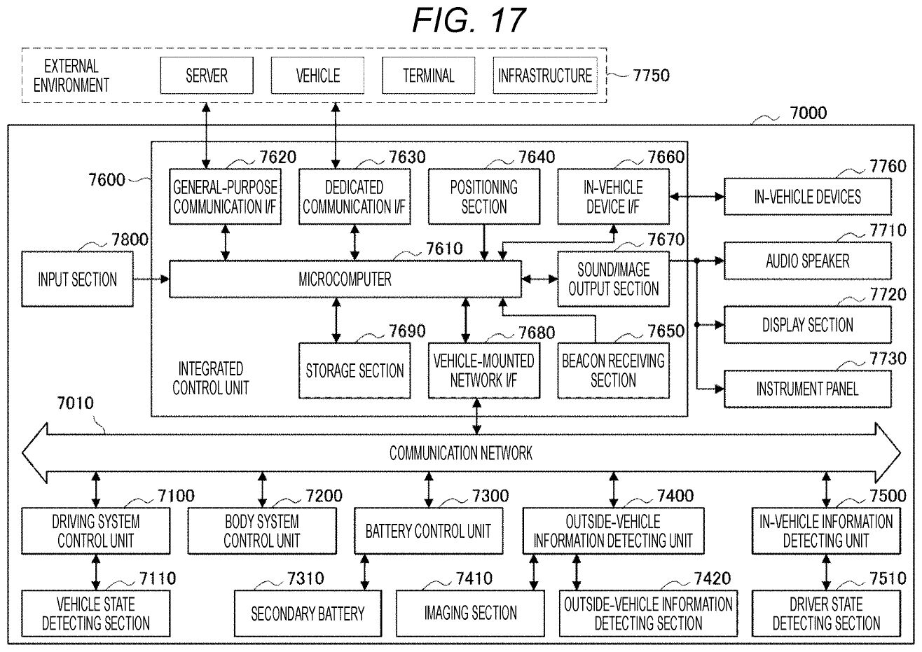

FIG. 17 is a block diagram illustrating an example of a schematic configuration of a vehicle control system 7000 as an example of a mobile object control system to which the technology according to the present disclosure is applied. The vehicle control system 7000 includes a plurality of electronic control units connected to each other via a communication network 7010. In the example illustrated in FIG. 17, the vehicle control system 7000 includes a driving system control unit 7100, a body system control unit 7200, a battery control unit 7300, an outside-vehicle information detecting unit 7400, an in-vehicle information detecting unit 7500, and an integrated control unit 7600. The communication network 7010 connecting the plurality of control units to each other may, for example, be a vehicle-mounted communication network compliant with an arbitrary standard such as controller area network (CAN), local interconnect network (LIN), local area network (LAN), FlexRay (registered trademark), or the like.

Each of the control units includes: a microcomputer that performs arithmetic processing according to various kinds of programs; a storage section that stores the programs executed by the microcomputer, parameters used for various kinds of operations, or the like; and a driving circuit that drives various kinds of control target devices. Each of the control units further includes: a network interface (I/F) for performing communication with other control units via the communication network 7010; and a communication I/F for performing communication with a device, a sensor, or the like within and without the vehicle by wire communication or radio communication. The functional components of the integrated control unit 7600 illustrated in FIG. 17 include a microcomputer 7610, a general-purpose communication I/F 7620, a dedicated communication I/F 7630, a positioning section 7640, a beacon receiving section 7650, an in-vehicle device I/F 7660, a sound/image output section 7670, a vehicle-mounted network I/F 7680, and a storage section 7690. The other control units similarly include a microcomputer, a communication I/F, a storage section, and the like.

The driving system control unit 7100 controls the operation of devices related to the driving system of the vehicle in accordance with various kinds of programs. For example, the driving system control unit 7100 functions as a control device for a driving force generating device for generating the driving force of the vehicle, such as an internal combustion engine, a driving motor, or the like, a driving force transmitting mechanism for transmitting the driving force to wheels, a steering mechanism for adjusting the steering angle of the vehicle, a braking device for generating the braking force of the vehicle, and the like. The driving system control unit 7100 may have a function as a control device of an antilock brake system (ABS), electronic stability control (ESC), or the like.

The driving system control unit 7100 is connected with a vehicle state detecting section 7110. The vehicle state detecting section 7110, for example, includes at least one of a gyro sensor that detects the angular velocity of axial rotational movement of a vehicle body, an acceleration sensor that detects the acceleration of the vehicle, and sensors for detecting an amount of operation of an accelerator pedal, an amount of operation of a brake pedal, the steering angle of a steering wheel, an engine speed or the rotational speed of wheels, and the like. The driving system control unit 7100 performs arithmetic processing using a signal input from the vehicle state detecting section 7110, and controls the internal combustion engine, the driving motor, an electric power steering device, the brake device, and the like.

The body system control unit 7200 controls the operation of various kinds of devices provided to the vehicle body in accordance with various kinds of programs. For example, the body system control unit 7200 functions as a control device for a keyless entry system, a smart key system, a power window device, or various kinds of lamps such as a headlamp, a backup lamp, a brake lamp, a turn signal, a fog lamp, or the like. In this case, radio waves transmitted from a mobile device as an alternative to a key or signals of various kinds of switches can be input to the body system control unit 7200. The body system control unit 7200 receives these input radio waves or signals, and controls a door lock device, the power window device, the lamps, or the like of the vehicle.

The battery control unit 7300 controls a secondary battery 7310, which is a power supply source for the driving motor, in accordance with various kinds of programs. For example, the battery control unit 7300 is supplied with information about a battery temperature, a battery output voltage, an amount of charge remaining in the battery, or the like from a battery device including the secondary battery 7310. The battery control unit 7300 performs arithmetic processing using these signals, and performs control for regulating the temperature of the secondary battery 7310 or controls a cooling device provided to the battery device or the like.

The outside-vehicle information detecting unit 7400 detects information about the outside of the vehicle including the vehicle control system 7000. For example, the outside-vehicle information detecting unit 7400 is connected with at least one of an imaging section 7410 and an outside-vehicle information detecting section 7420. The imaging section 7410 includes at least one of a time-of-flight (ToF) camera, a stereo camera, a monocular camera, an infrared camera, and other cameras. The outside-vehicle information detecting section 7420, for example, includes at least one of an environmental sensor for detecting current atmospheric conditions or weather conditions and a peripheral information detecting sensor for detecting another vehicle, an obstacle, a pedestrian, or the like on the periphery of the vehicle including the vehicle control system 7000.

The environmental sensor, for example, may be at least one of a rain drop sensor detecting rain, a fog sensor detecting a fog, a sunshine sensor detecting a degree of sunshine, and a snow sensor detecting a snowfall. The peripheral information detecting sensor may be at least one of an ultrasonic sensor, a radar device, and a LIDAR device (Light detection and Ranging device, or Laser imaging detection and ranging device). Each of the imaging section 7410 and the outside-vehicle information detecting section 7420 may be provided as an independent sensor or device, or may be provided as a device in which a plurality of sensors or devices are integrated.

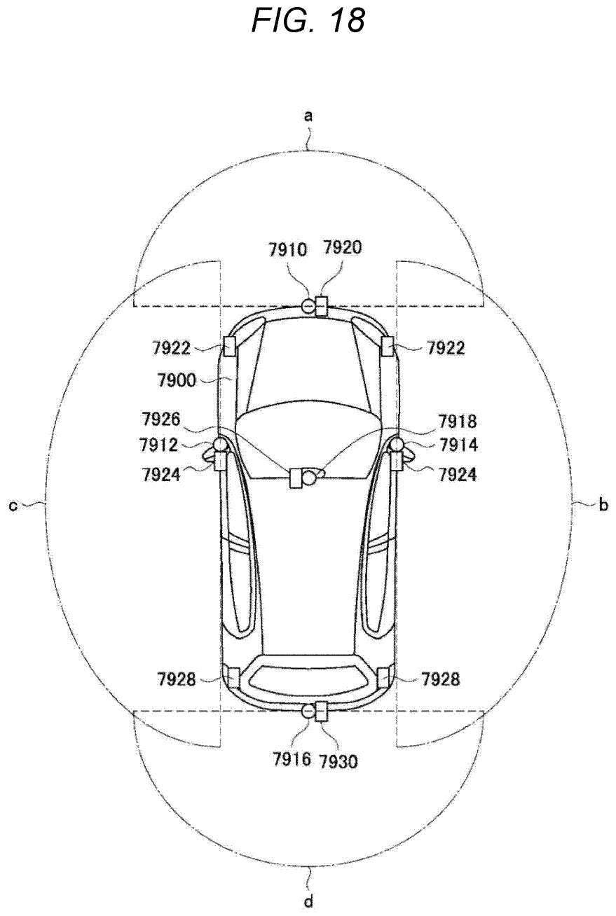

Here, FIG. 18 illustrates an example of installation positions of the imaging section 7410 and the outside-vehicle information detecting section 7420. Imaging sections 7910, 7912, 7914, 7916, and 7918 are, for example, disposed at least one of positions on a front nose, sideview mirrors, a rear bumper, and a back door of the vehicle 7900 and a position on an upper portion of a windshield within the interior of the vehicle. The imaging section 7910 provided to the front nose and the imaging section 7918 provided to the upper portion of the windshield within the interior of the vehicle obtain mainly an image of the front of the vehicle 7900. The imaging sections 7912 and 7914 provided to the sideview mirrors obtain mainly an image of the sides of the vehicle 7900. The imaging section 7916 provided to the rear bumper or the back door obtains mainly an image of the rear of the vehicle 7900. The imaging section 7918 provided to the upper portion of the windshield within the interior of the vehicle is used mainly to detect a preceding vehicle, a pedestrian, an obstacle, a signal, a traffic sign, a lane, or the like.

Note that FIG. 18 illustrates an example of the imaging range of each of the imaging sections 7910, 7912, 7914, and 7916. An imaging range a represents the imaging range of the imaging section 7910 provided to the front nose. Imaging ranges b and c respectively represent the imaging ranges of the imaging sections 7912 and 7914 provided to the sideview mirrors. An imaging range d represents the imaging range of the imaging section 7916 provided to the rear bumper or the back door. A bird's-eye image of the vehicle 7900 as viewed from above can be obtained by superimposing image data imaged by the imaging sections 7910, 7912, 7914, and 7916, for example.

Outside-vehicle information detecting sections 7920, 7922, 7924, 7926, 7928, and 7930 provided to the front, rear, sides, and corners of the vehicle 7900 and the upper portion of the windshield within the interior of the vehicle may be, for example, an ultrasonic sensor or a radar device. The outside-vehicle information detecting sections 7920, 7926, and 7930 provided to the front nose of the vehicle 7900, the rear bumper, the back door of the vehicle 7900, and the upper portion of the windshield within the interior of the vehicle may be a LIDAR device, for example. These outside-vehicle information detecting sections 7920 to 7930 are used mainly to detect a preceding vehicle, a pedestrian, an obstacle, or the like.

Referring back to FIG. 17, the description will be continued. The outside-vehicle information detecting unit 7400 makes the imaging section 7410 image an image of the outside of the vehicle, and receives imaged image data. In addition, the outside-vehicle information detecting unit 7400 receives detection information from the outside-vehicle information detecting section 7420 connected to the outside-vehicle information detecting unit 7400. In a case where the outside-vehicle information detecting section 7420 is an ultrasonic sensor, a radar device, or a LIDAR device, the outside-vehicle information detecting unit 7400 transmits an ultrasonic wave, an electromagnetic wave, or the like, and receives information of a received reflected wave. On the basis of the received information, the outside-vehicle information detecting unit 7400 may perform processing of detecting an object such as a human, a vehicle, an obstacle, a sign, a character on a road surface, or the like, or processing of detecting a distance thereto. The outside-vehicle information detecting unit 7400 may perform environment recognition processing of recognizing a rainfall, a fog, road surface conditions, or the like on the basis of the received information. The outside-vehicle information detecting unit 7400 may calculate a distance to an object outside the vehicle on the basis of the received information.

In addition, on the basis of the received image data, the outside-vehicle information detecting unit 7400 may perform image recognition processing of recognizing a human, a vehicle, an obstacle, a sign, a character on a road surface, or the like, or processing of detecting a distance thereto. The outside-vehicle information detecting unit 7400 may subject the received image data to processing such as distortion correction, alignment, or the like, and combine the image data imaged by a plurality of different imaging sections 7410 to generate a bird's-eye image or a panoramic image. The outside-vehicle information detecting unit 7400 may perform viewpoint conversion processing using the image data imaged by the imaging section 7410 including the different imaging parts.

The in-vehicle information detecting unit 7500 detects information about the inside of the vehicle. The in-vehicle information detecting unit 7500 is, for example, connected with a driver state detecting section 7510 that detects the state of a driver. The driver state detecting section 7510 may include a camera that images the driver, a biosensor that detects biological information of the driver, a microphone that collects sound within the interior of the vehicle, or the like. The biosensor is, for example, disposed in a seat surface, the steering wheel, or the like, and detects biological information of an occupant sitting in a seat or the driver holding the steering wheel. On the basis of detection information input from the driver state detecting section 7510, the in-vehicle information detecting unit 7500 may calculate a degree of fatigue of the driver or a degree of concentration of the driver, or may determine whether the driver is dozing. The in-vehicle information detecting unit 7500 may subject an audio signal obtained by the collection of the sound to processing such as noise canceling processing or the like.

The integrated control unit 7600 controls general operation within the vehicle control system 7000 in accordance with various kinds of programs. The integrated control unit 7600 is connected with an input section 7800. The input section 7800 is implemented by a device capable of input operation by an occupant, such, for example, as a touch panel, a button, a microphone, a switch, a lever, or the like. The integrated control unit 7600 may be supplied with data obtained by voice recognition of voice input through the microphone. The input section 7800 may, for example, be a remote control device using infrared rays or other radio waves, or an external connecting device such as a mobile telephone, a personal digital assistant (PDA), or the like that supports operation of the vehicle control system 7000. The input section 7800 may be, for example, a camera. In that case, an occupant can input information by gesture. Alternatively, data may be input which is obtained by detecting the movement of a wearable device that an occupant wears. Further, the input section 7800 may, for example, include an input control circuit or the like that generates an input signal on the basis of information input by an occupant or the like using the above-described input section 7800, and which outputs the generated input signal to the integrated control unit 7600. An occupant or the like inputs various kinds of data or gives an instruction for processing operation to the vehicle control system 7000 by operating the input section 7800.

The storage section 7690 may include a read only memory (ROM) that stores various kinds of programs executed by the microcomputer and a random access memory (RAM) that stores various kinds of parameters, operation results, sensor values, or the like. In addition, the storage section 7690 may be implemented by a magnetic storage device such as a hard disc drive (HDD) or the like, a semiconductor storage device, an optical storage device, a magneto-optical storage device, or the like.

The general-purpose communication I/F 7620 is a communication I/F used widely, which communication I/F mediates communication with various apparatuses present in an external environment 7750. The general-purpose communication I/F 7620 may implement a cellular communication protocol such as global system for mobile communications (GSM (registered trademark)), worldwide interoperability for microwave access (WiMAX (registered trademark)), long term evolution (LTE (registered trademark)), LTE-advanced (LTE-A), or the like, or another wireless communication protocol such as wireless LAN (referred to also as wireless fidelity (Wi-Fi (registered trademark)), Bluetooth (registered trademark), or the like. The general-purpose communication I/F 7620 may, for example, connect to an apparatus (for example, an application server or a control server) present on an external network (for example, the Internet, a cloud network, or a company-specific network) via a base station or an access point. In addition, the general-purpose communication I/F 7620 may connect to a terminal present in the vicinity of the vehicle (which terminal is, for example, a terminal of the driver, a pedestrian, or a store, or a machine type communication (MTC) terminal) using a peer to peer (P2P) technology, for example.

The dedicated communication I/F 7630 is a communication I/F that supports a communication protocol developed for use in vehicles. The dedicated communication I/F 7630 may implement a standard protocol such, for example, as wireless access in vehicle environment (WAVE), which is a combination of institute of electrical and electronic engineers (IEEE) 802.11p as a lower layer and IEEE 1609 as a higher layer, dedicated short range communications (DSRC), or a cellular communication protocol. The dedicated communication I/F 7630 typically carries out V2X communication as a concept including one or more of communication between a vehicle and a vehicle (Vehicle to Vehicle), communication between a road and a vehicle (Vehicle to Infrastructure), communication between a vehicle and a home (Vehicle to Home), and communication between a pedestrian and a vehicle (Vehicle to Pedestrian).

The positioning section 7640, for example, performs positioning by receiving a global navigation satellite system (GNSS) signal from a GNSS satellite (for example, a GPS signal from a global positioning system (GPS) satellite), and generates positional information including the latitude, longitude, and altitude of the vehicle. Incidentally, the positioning section 7640 may identify a current position by exchanging signals with a wireless access point, or may obtain the positional information from a terminal such as a mobile telephone, a personal handyphone system (PHS), or a smart phone that has a positioning function.

The beacon receiving section 7650, for example, receives a radio wave or an electromagnetic wave transmitted from a radio station installed on a road or the like, and thereby obtains information about the current position, congestion, a closed road, a necessary time, or the like. Incidentally, the function of the beacon receiving section 7650 may be included in the dedicated communication I/F 7630 described above.

The in-vehicle device I/F 7660 is a communication interface that mediates connection between the microcomputer 7610 and various in-vehicle devices 7760 present within the vehicle. The in-vehicle device I/F 7660 may establish wireless connection using a wireless communication protocol such as wireless LAN, Bluetooth (registered trademark), near field communication (NFC), or wireless universal serial bus (WUSB). In addition, the in-vehicle device I/F 7660 may establish wired connection by universal serial bus (USB), high-definition multimedia interface (HDMI (registered trademark)), mobile high-definition link (MHL), or the like via a connection terminal (and a cable if necessary) not depicted in the figures. The in-vehicle devices 7760 may, for example, include at least one of a mobile device and a wearable device possessed by an occupant and an information device carried into or attached to the vehicle. The in-vehicle devices 7760 may also include a navigation device that searches for a path to an arbitrary destination. The in-vehicle device I/F 7660 exchanges control signals or data signals with these in-vehicle devices 7760.

The vehicle-mounted network I/F 7680 is an interface that mediates communication between the microcomputer 7610 and the communication network 7010. The vehicle-mounted network I/F 7680 transmits and receives signals or the like in conformity with a predetermined protocol supported by the communication network 7010.

The microcomputer 7610 of the integrated control unit 7600 controls the vehicle control system 7000 in accordance with various kinds of programs on the basis of information obtained via at least one of the general-purpose communication I/F 7620, the dedicated communication I/F 7630, the positioning section 7640, the beacon receiving section 7650, the in-vehicle device I/F 7660, and the vehicle-mounted network I/F 7680. For example, the microcomputer 7610 may calculate a control target value for the driving force generating device, the steering mechanism, or the braking device on the basis of the obtained information about the inside and outside of the vehicle, and output a control command to the driving system control unit 7100. For example, the microcomputer 7610 may perform cooperative control intended to implement functions of an advanced driver assistance system (ADAS) which functions include collision avoidance or shock mitigation for the vehicle, following driving based on a following distance, vehicle speed maintaining driving, a warning of collision of the vehicle, a warning of deviation of the vehicle from a lane, or the like. In addition, the microcomputer 7610 may perform cooperative control intended for automated driving, which makes the vehicle to travel automatedly without depending on the operation of the driver, or the like, by controlling the driving force generating device, the steering mechanism, the braking device, or the like on the basis of the obtained information about the surroundings of the vehicle.

The microcomputer 7610 may generate three-dimensional distance information between the vehicle and an object such as a surrounding structure, a person, or the like, and generate local map information including information about the surroundings of the current position of the vehicle, on the basis of information obtained via at least one of the general-purpose communication I/F 7620, the dedicated communication I/F 7630, the positioning section 7640, the beacon receiving section 7650, the in-vehicle device I/F 7660, and the vehicle-mounted network I/F 7680. In addition, the microcomputer 7610 may predict danger such as collision of the vehicle, approaching of a pedestrian or the like, an entry to a closed road, or the like on the basis of the obtained information, and generate a warning signal. The warning signal may, for example, be a signal for producing a warning sound or lighting a warning lamp.

The sound/image output section 7670 transmits an output signal of at least one of a sound and an image to an output device capable of visually or auditorily notifying information to an occupant of the vehicle or the outside of the vehicle. In the example in FIG. 17, an audio speaker 7710, a display section 7720, and an instrument panel 7730 are illustrated as examples of the output device. The display section 7720 may, for example, include at least one of an on-board display and a head-up display. The display section 7720 may have an augmented reality (AR) display function. The output device may be other than these devices, and may be another device such as headphones, a wearable device such as an eyeglass type display worn by an occupant or the like, a projector, a lamp, or the like. In a case where the output device is a display device, the display device visually displays results obtained by various kinds of processing performed by the microcomputer 7610 or information received from another control unit in various forms such as text, an image, a table, a graph, or the like. In addition, in a case where the output device is an audio output device, the audio output device converts an audio signal constituted of reproduced audio data or sound data or the like into an analog signal, and auditorily outputs the analog signal.

Note that, in the example illustrated in FIG. 17, at least two control units connected via the communication network 7010 may be integrated as one control unit. Alternatively, each individual control unit may include a plurality of control units. Further, the vehicle control system 7000 may include another control unit not depicted in the figures. In addition, part or the whole of the functions performed by one of the control units in the above description may be assigned to another control unit. That is, predetermined arithmetic processing may be performed by any of the control units as long as information is transmitted and received via the communication network 7010. Similarly, a sensor or a device connected to one of the control units may be connected to another control unit, and a plurality of control units may mutually transmit and receive detection information via the communication network 7010.

Note that the present technology may have the following configurations.

(1) A photodetection device including
a semiconductor substrate having a pixel region in which a plurality of pixels that perform photoelectric conversion is disposed,
in which the semiconductor substrate includes:
a groove portion that is disposed on an outer peripheral side of the pixel region, has a smaller height than a height of the pixel region, and extends along a plurality of sides;
a protruding portion that is provided on an outer peripheral side of the groove portion, has a greater height than the height of the groove portion, and extends along the plurality of sides; and
a covering film that covers an entire region of a surface on a light incident surface side of the protruding portion on at least one side of the plurality of sides.

(2) The photodetection device according to (1), in which a reflectance of the covering film is lower than a reflectance of the semiconductor substrate.

(3) The photodetection device according to (1) or (2), in which the groove portion is disposed to surround the pixel region, and
the protruding portion is disposed so as to surround the groove portion.

(4) The photodetection device according to any one of (1) to (3), in which a diced cutting surface of the semiconductor substrate is disposed on an outer peripheral side of the protruding portion.

(5) The photodetection device according to any one of (1) to (4), in which a side covered with the covering film among the plurality of sides of the semiconductor substrate is a side on which wire bonding pads are not disposed.

(6) The photodetection device according to any one of (1) to (5), in which a distance between the pixel region and the groove portion differs between at least two sides among the plurality of sides of the semiconductor substrate.

(7) The photodetection device according to (6), in which the distance on a side on which a wire bonding pad is disposed is longer than the distance on a side on which a wire bonding pad is not disposed, and
the side covered with the covering film includes a side on which a wire bonding pad is not disposed.

(8) The photodetection device according to any one of (1) to (7), in which a height of the protruding portion is the same as a height of the pixel region.

(9) The photodetection device according to any one of (1) to (8), further including a test terminal disposed on part of the side covered with the covering film,
in which the covering film covers a surface of the side on which the test terminal is disposed.

(10) The photodetection device according to any one of (1) to (9), in which a sidewall of the protruding portion at a portion in contact with the groove portion is a surface extending from a bottom surface of the groove portion to an upper surface of the protruding portion, and the surface has an uneven structure.

(11) The photodetection device according to any one of (1) to (9), in which a sidewall of the protruding portion at a portion in contact with the groove portion is a flat surface extending from a bottom surface of the groove portion to an upper surface of the protruding portion.

(12) The photodetection device according to any one of (1) to (9), in which a sidewall of the protruding portion at a portion in contact with the groove portion has a step.

(13) The photodetection device according to any one of (1) to (12), in which the covering film includes an oxide film having a lower reflectance than a reflectance of the semiconductor substrate.

(14) The photodetection device according to (13),
in which the covering film includes a stack structure in which a planarizing film containing a resin and the oxide film are stacked.

(15) The photodetection device according to (14), in which the planarizing film is the same material as a film for planarizing an upper surface of a color filter layer disposed on the pixel region.

(16) The photodetection device according to any one of (1) to (15), in which a thickness of the covering film is not smaller than 50 nm and not greater than 120 nm.

(17) A photodetection device including
a semiconductor substrate having a pixel region in which a plurality of pixels that perform photoelectric conversion is disposed,
in which the semiconductor substrate includes:
a groove portion that is disposed on an outer side of the pixel region, has a smaller height than a height of the pixel region, and extends along a plurality of sides; and
a first protruding portion that is disposed on an outer side of the groove portion, has a greater height than the height of the groove portion, and extends along the plurality of sides,
a sidewall of the first protruding portion on a side in contact with the groove portion has an uneven structure, and
an upper surface of the first protruding portion is flat.

(18) The photodetection device according to (17),
in which a predetermined region from an end side of an upper surface continuing to the sidewall of the first protruding portion in contact with the groove portion is flat.

(19) The photodetection device according to (18),
in which a sidewall on an outer side of the first protruding portion includes a dicing surface, and,
of the upper surface of the first protruding portion, the predetermined region inwardly away from the dicing surface by at least 5 μm is flat.

(20) The photodetection device according to any one of (17) to (19),
in which the sidewall of the first protruding portion on the side in contact with the groove portion is inclined at least a predetermined angle with respect to a normal direction of the upper surface of the first protruding portion.

(21) The photodetection device according to any one of (17) to (20),
in which the first protruding portion has a single-layer structure containing silicon as a material.

(22) The photodetection device according to any one of (17) to (20),
in which the first protruding portion has a stack structure,
the first protruding portion includes a covering film disposed to be in contact with the upper surface, and a silicon layer stacked on the covering film, and
a reflectance of the covering film is lower than a reflectance of the silicon layer.

(23) The photodetection device according to any one of (17) to (22), further including
a scribe region disposed to surround the pixel region, in which the scribe region includes:
a second protruding portion that is disposed on an inner side of the groove portion, has a greater height than a height of the groove portion, and is disposed to surround the pixel region;
the groove portion disposed to surround the second protruding portion; and
the first protruding portion disposed to surround the groove portion.

(24) The photodetection device according to (23), further including
wire bonding pads disposed along at least two sides among a plurality of sides of the pixel region, in which
the scribe region is disposed on an outer side of the pads.

Aspects of the present disclosure are not limited to the above-described respective embodiments, but include various modifications that can be conceived by those skilled in the art, and the effects of the present disclosure are not limited to those mentioned above. That is, various additions, modifications, and partial deletions are possible without departing from the conceptual idea and spirit of the present disclosure derived from the matters defined in the claims and equivalents thereof.

### REFERENCE SIGNS LIST

1 Photodetection device
2 Pixel region
3 Vertical drive circuit
4 Column signal processing circuit
5 Horizontal drive circuit
6 Output circuit
7 Control circuit
8 Pixel
8a On-chip lens
11 First wafer
12 First chip
12a First semiconductor substrate
12b First wiring layer
13 Scribe region
13a Thick line region
13b Groove portion
13c Protruding portion
13d Sidewall surface
13e Uneven structure
14 Pad
15 Second chip
15a Second semiconductor substrate
15b Second wiring layer
16 Peripheral region
17 Color filter layer
18 Planarizing film
19 LTO
20 Camera module
21 Imaging lens
22 Lens holder
23 Covering film
23a Planarizing film
23b Oxide film
24 Test terminal

What is claimed is:

1. A photodetection device comprising
a semiconductor substrate having a pixel region in which a plurality of pixels that perform photoelectric conversion is disposed,
wherein the semiconductor substrate includes:
a groove portion that is disposed on an outer peripheral side of the pixel region, has a smaller height than a height of the pixel region, and extends along a plurality of sides;
a protruding portion that is provided on an outer peripheral side of the groove portion, has a greater height than the height of the groove portion, and extends along the plurality of sides; and
a covering film that covers an entire region of a surface on a light incident surface side of the protruding portion on at least one side of the plurality of sides.

2. The photodetection device according to claim 1, wherein a reflectance of the covering film is lower than a reflectance of the semiconductor substrate.

3. The photodetection device according to claim 1, wherein the groove portion is disposed to surround the pixel region, and
the protruding portion is disposed to surround the groove portion.

4. The photodetection device according to claim 1, wherein a diced cutting surface of the semiconductor substrate is disposed on an outer peripheral side of the protruding portion.

5. The photodetection device according to claim 1, wherein a side covered with the covering film among the plurality of sides of the semiconductor substrate is a side on which wire bonding pads are not disposed.

6. The photodetection device according to claim 1, wherein a distance between the pixel region and the groove portion differs between at least two sides among the plurality of sides of the semiconductor substrate.

7. The photodetection device according to claim 6, wherein the distance on a side on which a wire bonding pad is disposed is longer than the distance on a side on which a wire bonding pad is not disposed, and
the side covered with the covering film includes a side on which a wire bonding pad is not disposed.

8. The photodetection device according to claim 1, wherein a height of the protruding portion is the same as a height of the pixel region.

9. The photodetection device according to claim 1, further comprising a test terminal disposed on part of the side covered with the covering film,
wherein the covering film covers a surface of the side on which the test terminal is disposed.

10. The photodetection device according to claim 1, wherein a sidewall of the protruding portion at a portion in contact with the groove portion includes a surface extending from a bottom surface of the groove portion to an upper surface of the protruding portion, and the surface has an uneven structure.

11. The photodetection device according to claim 1, wherein a sidewall of the protruding portion at a portion in contact with the groove portion includes a flat surface extending from a bottom surface of the groove portion to an upper surface of the protruding portion.

12. The photodetection device according to claim 1, wherein a sidewall of the protruding portion at a portion in contact with the groove portion has a step.

13. The photodetection device according to claim 1, wherein the covering film includes an oxide film having a lower reflectance than a reflectance of the semiconductor substrate.

14. The photodetection device according to claim 13,
wherein the covering film includes a stack structure in which a planarizing film containing a resin and the oxide film are stacked.

15. The photodetection device according to claim 14, wherein the planarizing film includes the same material as a film for planarizing an upper surface of a color filter layer disposed on the pixel region.

16. The photodetection device according to claim 1, wherein a thickness of the covering film is not smaller than 50 nm and not greater than 120 nm.

17. A photodetection device comprising
a semiconductor substrate having a pixel region in which a plurality of pixels that perform photoelectric conversion is disposed,
wherein the semiconductor substrate includes:
a groove portion that is disposed on an outer side of the pixel region, has a smaller height than a height of the pixel region, and extends along a plurality of sides; and
a first protruding portion that is disposed on an outer side of the groove portion, has a greater height than the height of the groove portion, and extends along the plurality of sides;
a sidewall of the first protruding portion on a side in contact with the groove portion has an uneven structure; and
an upper surface of the first protruding portion is flat.

18. The photodetection device according to claim 17,
wherein a predetermined region from an end side of an upper surface continuing to the sidewall of the first protruding portion in contact with the groove portion is flat.

19. The photodetection device according to claim 18,
wherein a sidewall on an outer side of the first protruding portion includes a dicing surface, and,
of the upper surface of the first protruding portion, the predetermined region inwardly away from the dicing surface by at least 5 μm is flat.

20. The photodetection device according to claim 17,
wherein the sidewall of the first protruding portion on the side in contact with the groove portion is inclined at least a predetermined angle with respect to a normal direction of the upper surface of the first protruding portion.

21. The photodetection device according to claim 17,
wherein the first protruding portion has a single-layer structure containing silicon as a material.

22. The photodetection device according to claim 17,
wherein the first protruding portion has a stack structure,
the first protruding portion includes a covering film disposed to be in contact with the upper surface, and a silicon layer stacked on the covering film, and
a reflectance of the covering film is lower than a reflectance of the silicon layer.

23. The photodetection device according to claim 17, further comprising
a scribe region disposed to surround the pixel region,
wherein the scribe region includes:
a second protruding portion that is disposed on an inner side of the groove portion, has a greater height than a height of the groove portion, and is disposed to surround the pixel region;
the groove portion disposed to surround the second protruding portion; and
the first protruding portion disposed to surround the groove portion.

24. The photodetection device according to claim 23, further comprising
wire bonding pads disposed along at least two sides among the plurality of sides of the pixel region,
wherein the scribe region is disposed on an outer side of the pads.
